(19) United States
(12) Patent Application Publication
(10) Pub. No.: US 2009/0074947 A1
(43) Pub. Date: Mar. 19, 2009

(54) METHOD FOR COATING FILM FORMATION, APPARATUS FOR COATING FILM FORMATION, AND METHOD FOR TONING COATING MATERIAL PREPARATION

(75) Inventor: Tohru Takeuchi, Kanagawa (JP)

Correspondence Address: KNOBBE MARTENS OLSON & BEAR LLP, 2040 MAIN STREET, FOURTEENTH FLOOR, IRVINE, CA, 92614, US

(73) Assignee: Kansai Paint Co., Ltd., Hyogo (JP)

(21) Appl. No.: 11/719,136

(22) PCT Filed: Nov. 18, 2005
(86) PCT No.: PCT/JP05/21300

§ 371 Date: May 11, 2007

(30) Foreign Application Priority Data
Nov. 19, 2004 (JP) 2004-336434

(51) Int. Cl. C23C 16/52

(52) U.S. Cl. 427/8; 118/666

(57) ABSTRACT

The present invention provides a method for forming coated films and equipment for forming coating films which can effectively form coated films having substantially the same qualities as those formed under coating conditions in an actual coating operation, and a method for effectively reproduce color-toning coating materials having a desired color-toning.

The method for forming a coated film, which aims to reproduce finished qualities of a coated film to be obtained in an actual coating operation by spraying a coating material onto an object to be coated, includes: an air conditioning step of controlling the temperature and humidity in a coating booth (22) in accordance with the spraybooth conditions in the actual coating operation; and a coating step of forming a coated film on an object to be coated in the coating booth (22) using an atomizer (30) for spraying a coating material; the coating step comprising:
a coating condition determination step of controlling particle diameter, concentration and velocity of the atomized particles in a spray pattern of a coating material sprayed from the coating material atomizer (30) in accordance with those in the actual coating operation; and a coated film formation step of controlling the relative movement of the coating material atomizer (30) and the object to be coated (50) based on a coated film formation profile determined by the relation between changes in the coated film formation time in the actual coating operation and the resulting coated film thickness.

### TECHNICAL FIELD

The present invention relates to a method and equipment for forming coating films, and to a method for preparing color-toning coating materials.

### BACKGROUND OF THE INVENTION

In color-toning operations conducted at coating material production sites, color-toning centers, etc., a coated chip is generally prepared for each color in order to check the brightness, hue, and other aspects of a coated film obtained using the color-toned coating material. The color-toned coating materials are then delivered to worksites and used in coating. In coating operations, particularly for automobiles, home appliances and other industrial products, coating is conducted under strictly controlled air conditions. Therefore, the color-toning of coating materials is required so that a coated film having desired finished qualities (orientation of brightening material, color, etc.) can be obtained under specific coating conditions or spraybooth conditions in the desired coating operation. Therefore, coating material manufacturers, etc., need to prepare coated chips having finish qualities that result from being coated under the same coating conditions or spraybooth conditions as those in actual coating operations.

Conventionally, such coated chips are prepared using a coating facility having the same scale as that used in the actual coating operation so that the coating conditions, etc., are substantially the same as those in the actual coating operation.

When it is difficult to make the coating conditions, etc., under which coated films are obtained substantially the same as those in an actual coating operation due to differences in coating facilities, etc., coated films have been formed by the method disclosed in Patent Document 1. In the coating method disclosed in Patent Document 1, based on data regarding the qualities of coated films obtained with varying viscosities, flow rates, coating distances, temperatures, and other coating conditions in a coating booth, a relational expression between the coating conditions and the data of the resulting coated films is calculated. Using this relational expression, coating conditions which can be easily controlled are preferentially optimized while simulating the qualities of coated films obtained under various coating conditions so that the qualities of the obtained coated films are as similar as possible to those obtained under the same coating conditions of an actual coating operation.

### [Patent Document 1] Japanese Unexamined Patent Publication No. 2000-246167

### SUMMARY OF THE INVENTION

### Problem to be Solved by the Invention

When coated films are reproduced under substantially the same coating conditions as those in an actual coating operation by using a coating facility having the same scale as that used in the actual coating operation, the following problems may arise. In order to properly operate a coating facility, including a coating material tank, piping, pump, etc., it is necessary to supply a coating material to the coating facility in larger amounts than actually sprayed onto coated chips. Therefore, some of the coating material is wasted, particularly when few coatings are required and/or small quantities of various types of coated chips are produced. Furthermore, the entire coating booth equipped with the coating facility needs to be air-conditioned even when only small coated chips are produced, resulting in wasted energy.

When a coated film is formed on a coated chip by employing the method disclosed in Patent Document 1, it is necessary to obtain a relational expression between the coating conditions and the finished quality of the coated film by varying the viscosity, coating flow rate, coating distance, temperature in the coating booth, and other coating conditions so that the finished quality of the coated film can be estimated in advance. Since such operation requires many steps, it is difficult to effectively form a coated film on a chip with this method.

The present invention was accomplished to solve these problems. An object of the present invention is to provide a method for forming coated films and to provide equipment for forming coating films which can effectively form coated films having substantially the same qualities as those formed under coating conditions in an actual coating operation, and a method for effectively produce color-toning coating materials having particular color-toning.

### Means for Solving the Problem

The above-described object of the present invention can be achieved by a method for forming a coated film by spraying a coating material onto an object to be coated. The method aims to reproduce the finished quality of a coated film to be obtained in an actual coating operation and comprises an air conditioning step of controlling the temperature and humidity in a coating booth in accordance with the spraybooth conditions in the actual coating operation; and a coating step of forming a coated film on an object to be coated in the coating booth using an atomizer for spraying a coating material; the coating step comprising a coating condition determination step of controlling the particle diameter, concentration and velocity of atomized particles in the spray pattern of coating material sprayed from the coating material atomizer in accordance with those in the actual coating operation; and a coated film formation step of controlling the relative movement of the coating material atomizer and the object to be coated based on a coated film formation profile determined by the relation between changes in the coated film formation time in the actual coating operation and the resulting coated film thickness.

In this method for forming a coated film, it is preferable that the coated film formation step comprise a step of controlling the relative movement of the coating material atomizer and the object to be coated based on the coating pass velocity, number of coating passes, and length of the interval between the completion of one coating pass and the start of the subsequent coating pass in the spray pattern of the coating material sprayed from the coating material atomizer.

It is also preferable that the coating condition determination step comprise a step of selecting a suitable concentration of the atomized particles depending on the flow rate of the coating material sprayed from the coating material atomizer relative to the area of the pattern to be formed on the object by the spray pattern of coating material sprayed from the coating material atomizer.

It is preferable that the coating material atomizer be a rotational bell-type atomization coating device, and that the coating condition determination step comprise a step of selecting the particle diameter by suitably controlling the diameter and the rotational rate of the bell and the flow rate of the coating material from the rotational bell-type atomization coating device.

Furthermore, it is preferable that the coating material atomizer be a rotational bell-type atomization coating device, and the coating condition determination step comprise a step of determining the velocity of the atomized particles by suitably selecting the flow rate of shaping air from the rotational bell-type atomization coating device and the coating distance.

It is equally preferable that the coating material atomizer be a device for atomizing the coating material by using compressed air, and the coating condition determination step comprise a step of selecting the atomized particle diameter by suitably controlling the air flow rate and the flow rate of the coating material.

It is equally preferable that the coating material atomizer be a device for atomizing the coating material by using compressed air, and the coating condition determination step comprise a step of selecting the velocity of the atomized particles by suitably controlling the air flow rate and the coating distance.

The above-described object of the present invention also can be achieved by a device for forming a coating film, which aims to reproduce the finished quality of a coated film to be obtained by spraying a coating material onto an object to be coated in an actual coating operation. The device for forming a coating film comprises an air conditioner that can control temperature and humidity in a coating booth; a coating material sprayer for spraying a coating material onto an object to be coated in the coating booth; a conveyor for moving the object to be coated and the coating material sprayer in a relative manner in the coating booth; and a controller for controlling the operation of the air conditioner, the coating material sprayer, and the conveyor; the controller being able to control the particle diameter, concentration, and velocity of atomized particles sprayed from the coating material sprayer, and being able to control the relative movement of the coating material atomizer and the object to be coated based on a coated film formation profile determined by the relation between changes in the coated film formation time in an actual coating operation and the resulting coated film thickness.

It is preferable that the controller controls the movements of the coating material atomizer and the object to be coated in a relative manner based on the coating pass velocity, number of coating passes, and length of the interval between the completion of one coating pass and the start of the subsequent coating pass in the spray pattern of the coating material sprayed from the coating material atomizer.

It is preferable that the conveyor be a biaxial actuator.

The object of the present invention also can be achieved by a method for preparing a color-toning coating material, which aims to obtain a desired color-toning coating material, comprises a color measurement step for measuring color data of a color sample; a provisional compounding ratio determination step of provisionally determining the compounding ratio of coating materials of a plurality of primary colors based on the color data of the color sample measured in the color measurement step; a test coated film formation step of preparing a test coated film by spraying onto a test panel a color-toning coating material comprising coating materials of a plurality of primary colors prepared according to the provisional compounding ratio; a test coated film color measurement step of measuring color data of the test coated film formed in the test coated film formation step; a color evaluation step of evaluating the color conformity between the color sample and the test coated film by comparing color data of the color sample and those of the test coated film based on predetermined evaluation standards; the test coated film formation step comprising an air conditioning step of controlling the temperature and humidity in a coating booth in accordance with an actual coating operation; and a coating step of forming a test coated film on the test panel by spraying a color-toning coating material using a coating material atomizer in the coating booth; the coating step comprising a coating condition determination step of controlling the particle diameter, concentration and velocity of atomized particles in the spray pattern of coating material sprayed from the coating material atomizer in accordance with those in the actual coating operation; and a coated film formation step of controlling the movement of the coating material atomizer and the test panel to be coated in a relative manner based on a coated film formation profile determined by the relation between changes in the coated film formation time in the actual coating operation and the resulting coated film thickness.

In this method, it is preferable that the test coated film formation step comprise a step of forming a test coated film using a color-toning coating material prepared by modifying the provisional compounding ratio of primary color coating materials when it is determined that the color conformity does not meet evaluation standards in the color evaluation step.

### Effect of the Invention

The present invention provides a method for forming a coated film and equipment for forming coating films by which a coated film having the same finished quality as that formed under the coating conditions of an actual coating operation can be formed effectively. The present invention also provides a method for preparing a color-toning coating material by which desired color-toning coating materials can be effectively obtained.

### BRIEF DESCRIPTION OF DRAWINGS

FIG. 1 shows equipment for forming coating films according to one embodiment of the present invention wherein (a) is a cross-sectional view schematically showing its structure, and (b) is a plan-sectional view taken along the line A-A in FIG. 1(a).

FIG. 2 is an explanatory drawing showing the path of coating equipment over an object to be coated in an actual coating step.

FIG. 3 is an explanatory drawing of a coated film formation profile in an actual coating step.

FIG. 4 is a drawing explaining another coated film formation profile in an actual coating step.

FIG. 5 is a flow chart of a color-toning step in which color-toning coating material is prepared using the equipment for forming coating films of one embodiment.

### EXPLANATION OF NUMERICAL SYMBOLS

1 equipment for forming coating films
10 air conditioning system
15 piping
20 coating equipment main body
21 air supply chamber
22 coating booth
23 exhaust chamber
24 air supply filter
25 dust-collecting filter
30 rotational bell-type atomization coating device
40 conveyor storage member
41 conveyor
42 conveying jig
50 object to be coated

### BEST MODE FOR CARRYING OUT THE INVENTION

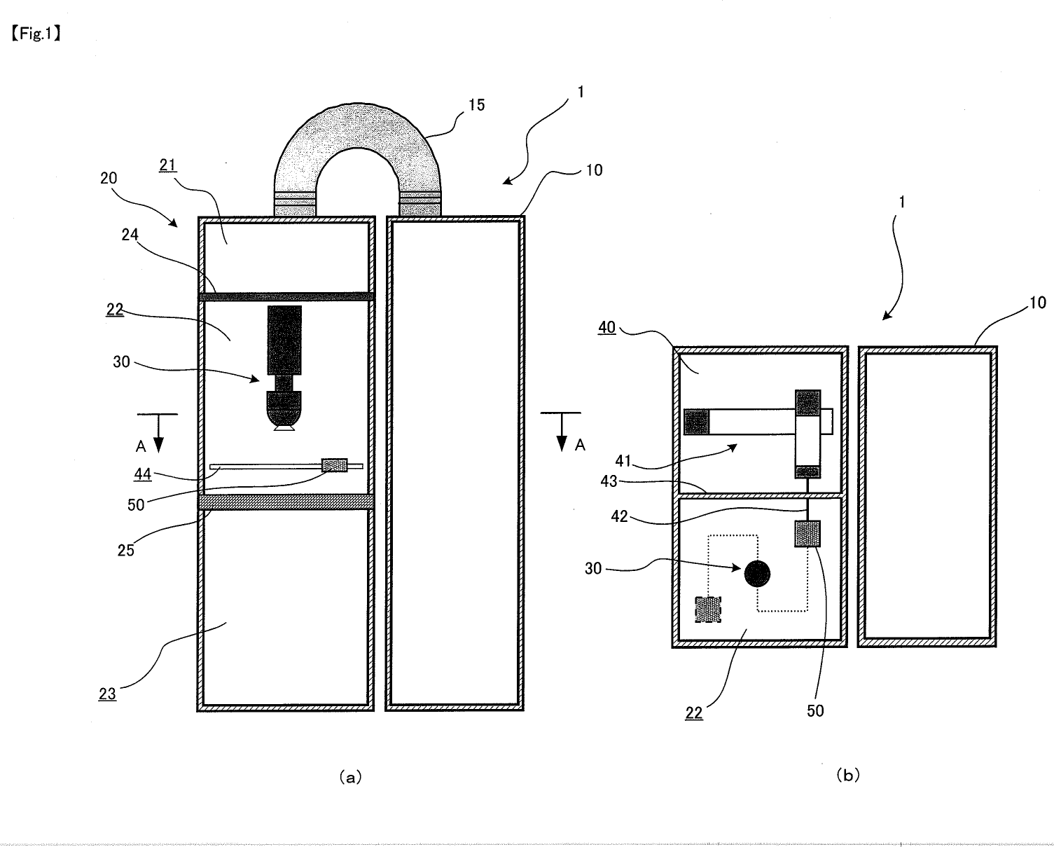

The equipment for forming coating films of the present invention is explained below with reference to the attached drawings. FIG. 1 is a cross-sectional view schematically showing the structure of equipment for forming coating films according to one embodiment of the present invention.

As shown in FIG. 1, the film forming equipment 1 comprises an air conditioning system 10, piping 15, coating equipment main body 20, conveyor storage member 40, and a controller (not shown). The air conditioning system 10 supplies air whose temperature and humidity is conditioned to the coating equipment main body 20, such that the air conditioning system 10 communicates with the coating equipment main body 20 at the top portions thereof via the piping 15.

The coating equipment main body 20 is divided from the top to downward into an air supply chamber 21, coating booth 22, and exhaust chamber 23, such that the air supply chamber 21 and the coating booth 22 are partitioned by an air supply filter 24, and the coating booth 22 and the exhaust chamber 23 are partitioned by a dust-collecting filter 25.

The air supply chamber 21 comprises a temperature detector and a humidity detector (not shown) for detecting the temperature and humidity of the air supply chamber 21. Examples of temperature detectors are temperature sensors such as thermisters and thermocouples. Humidity sensors such as high polymer film humidity sensors, ceramic humidity sensors, electrolyte humidity sensors can be used as humidity detectors.

The coating booth 22 comprises a rotational bell-type atomization coating device 30 which functions as a coating material atomizer. The rotational bell-type atomization coating device 30 comprises a bellcup that rotates at high speed on top of a coating gun, and the coating material discharged through the bellcup is atomized by centrifugal force generated by rotation of the bellcup. The rotational bell-type atomization coating device 30 comprises an air nozzle for emitting shaping air that controls the width of the spray pattern of the coating material by regulating the scattering direction of the atomized particles of the coating material which scatter from the peripheral edge of the bellcup in radially outward direction. The velocity of the atomized particles can be controlled by changing the flow rate of shaping air.

The rotational bell-type atomization coating device 30 is disposed in substantially the center of the coating booth 22 and a coating material supplier, air control panel, high-voltage generator, cables, etc. (not shown) are connected to the rotational bell-type atomization coating device 30. The rotational bell-type atomization coating device 30 is structured so that its distance from the object 50 can be varied.

Air-atomizing type coating devices and other various atomizers may be used as the coating material atomizer in place of the rotational bell-type atomization coating device 30. An air-atomizing type coating device comprises nozzles around a coating material outlet for jetting out compressed air (atomized air), and atomizes a coating material by discharging the coating material from the discharge outlet while jetting compressed air from the nozzles. An air-atomizing type coating device usually comprises pattern air nozzles at the periphery of the compressed air nozzles so as to control the width of the spray pattern.

An example of a coating material supplier is a syringe pump wherein a coating material is supplied by a microactuator pressing the piston portion of the syringe filled with a specific amount of coating material. The air control panel controls the air pressure for rotating the bell, the flow rate of shaping air, and other conditions of the rotational bell-type atomization coating device 30. A high-voltage generator applies atomized particles which have been made into fine particles by an atomizer to an object 50 using static electricity.

The exhaust chamber 23 comprises an exhauster (not shown) for discharging the air that was supplied by the air conditioning system 10.

As shown in the sectional view of FIG. 1(b), a conveyor storage member 40 is disposed adjacent to the coating booth 22, and comprises a conveyor 41. A spacer 44 having specific dimensions is formed beneath a partition 43 that separates the conveyor storage member 40 and the coating booth 22. The conveyor 41 comprises a conveying jig 42 for affixing the object 50 in the coating booth 22 via the space 44. A uniaxial actuator, biaxial actuator, etc., may be used as the conveyor 41; however, a biaxial actuator is preferable as it can freely transport the object 50 over one surface in the coating booth 22.

The controller is connected to the air conditioning system 10, temperature sensor, humidity sensor, rotational bell-type atomization coating device 30, and conveyor 41, and controls the operations thereof.

A method for forming a coated film having the same finished quality as in an actual coating operation using the film forming equipment 1 of the present embodiment is explained below.

Initially, a predetermined amount of coating material is supplied to the coating material supplier provided on the rotational bell-type atomization coating device 30. An object 50 is then affixed to the conveying jig 42 provided on the conveyor 41 in the coating booth 22. The air conditioning system 10, temperature sensor, humidity sensor, rotational bell-type atomization coating device 30, conveyor 41, exhauster and controller are operated by turning on the film forming equipment 1.

The air conditioning system 10 supplies air to the air supply chamber 21 via the piping 15. While feedbacking the signals output from the temperature and humidity sensors provided in the air supply chamber 21, the controller regulates the temperature and humidity of the air supplied from the air conditioning system 10 to be substantially the same as in the actual coating operation. The air whose temperature and humidity has been conditioned is fed to a coating booth 22 via an air supply filter 24. In this case, if necessary, the velocity of the air in the coating booth 22 whose temperature and humidity has been conditioned may be made substantially the same as that in the actual coating operation depending on the spraybooth conditions in the actual coating operation.

The rotational bell-type atomization coating device 30 conducts coating by spraying a coating material at substantially the same temperature and humidity as in a coating booth in an actual coating operation. The atomized particles of the sprayed coating material deposit on the object 50, forming a coated film. When a coated film is formed, the controller regulates the operation of the rotational bell-type atomization coating device 30 so that the particle diameter, concentration, and velocity of the atomized particles in the spray pattern of the coating material sprayed from the rotational bell-type atomization coating device 30 are substantially the same as in the actual coating operation. Furthermore, the controller regulates relative movement between the coating material atomizer 30 and the object 50 based on a coated film formation profile determined by the relation between changes in the coated film formation time and the thickness of the resulting coated film in the actual coating operation. The methods for selecting the particle diameter, concentration, and velocity of the atomized particles in the spray pattern, and controlling the relative movement between the coating material atomizer 30 and the object 50 are described later.

Excess atomized particles of coating material which do not deposit on the object 50 are carried by the air flow supplied from the air conditioning system 10 and sent toward the exhaust chamber 23. In this process, atomized particles of coating material are removed by a dust-collecting filter 25. The air passes through the dust-collecting filter 25 is sent to the exhaust chamber 23, and then discharged via an exhauster.

The methods for determining the particle diameter, concentration, and velocity of the atomized particles in the spray pattern of the coating material sprayed from the rotational bell-type atomization coating device 30 are explained below.

Herein, the atomized particle diameter is the average particle diameter of the particle swarm of atomized particles of coating material which have been atomized by a coating material atomizer measured when reaching the object 50. The particle diameter can be measured by a laser diffraction particle size analyzer, etc. The atomized particle concentration is the total volume of particles passed through a unit area of the spray pattern. As a simplified method, the atomized particle concentration may be assumed as an average atomized particle concentration calculated from the flow rate of the coating material relative to the area of the sprayed pattern. The pattern area can be easily obtained by spraying the spray pattern onto a plate, etc. The atomized particle velocity is an average particle velocity of the particle swarm in the object 50 direction when the atomized particles reach the object 50. The atomized particle velocity can be measured by, for example, a laser Doppler velocimeter, etc.

Specific methods for determining the particle diameter, concentration, and velocity of the atomized particles are explained in detail below. The particle diameter can be easily determined by suitably selecting the bellcup diameter of the rotational bell-type atomization coating device 30, the rotational speed of the bell, and flow rate of the coating material, etc., so that the particle diameter is substantially the same as that in the actual coating operation. The rotational speed of the bell can be controlled, for example, by varying the air pressure for rotating the bell of the rotational bell-type atomization coating device 30. The flow rate of the coating material can be controlled by varying the flow rate of the coating material supplier.

When an air-atomizing type coating equipment is used as the coating material atomizer, the particle diameter can be easily set so as to be substantially the same as that in the actual coating operation by suitably selecting the atomized air flow rate, flow rate of the coating material, etc. The atomized air flow rate can be controlled by reducing the volume of discharged air, etc.

Usually, a rotational bell-type atomization coating device used in an actual coating operation has a bellcup diameter of about 60 mmφ to 70 mmφ, its rotational speed is 20000-30000 rpm, and flow rate is 200 to 300 cc/min; however, when a small bellcup is used in the present embodiment, a particle diameter substantially the same as that in the actual coating operation can be obtained at a flow rate as small as about 20 to 30 cc/min and a rotational speed of about 10000 rpm.

The atomized particle concentration can be easily calculated based on the flow rate of the coating material relative to the pattern area formed on the object 50 by the spray pattern sprayed from the rotational bell-type atomization coating device 30. Therefore, an atomized particle concentration that is substantially the same as that in the actual coating operation can be easily obtained by controlling the flow rate of the coating material. For example, when the width of the coating pattern in an actual operation is to be 30 cm and the flow rate is to be 200 cc/min, if the width of the coating pattern in the present embodiment is set at 10 cm, the ratio of pattern area of the present embodiment/the actual operation is 1/9. Therefore, the same atomized particle concentration can be obtained by setting the flow rate at 22.2 cc/min (200×( 1/9)). Note that the width of the spray pattern can be easily changed by controlling the angle of the shaping air emitted from the rotational bell-type atomization coating device 30, and the flow rate thereof.

The atomized particle velocity can be easily made substantially the same as that in the actual coating operation by suitably selecting the flow rate of shaping air of the rotational bell-type atomization coating device 30, the coating distance, etc. Note that when air-atomizing type coating equipment is used as a coating material atomizer, by suitably selecting the atomized air flow rate and the coating distance, the atomized particle velocity can be easily made substantially the same as that in the actual coating operation.

As described above, by controlling the flow rate of the coating material of the rotational bell-type atomization coating device 30, bellcup diameter, the rotational speed of the bell, etc., it is possible to make the atomized conditions of the coating material (particle diameter, concentration, and velocity of the atomized particles) substantially the same as those of the coating material deposited on the object 50 in the actual coating operation.

A method for controlling the relative movement between the coating material atomizer 30 and the object 50 in the actual coating operation based on a coated film formation profile determined by the relation between changes in the coated film formation time and the thickness of the resulting coated film is explained below.

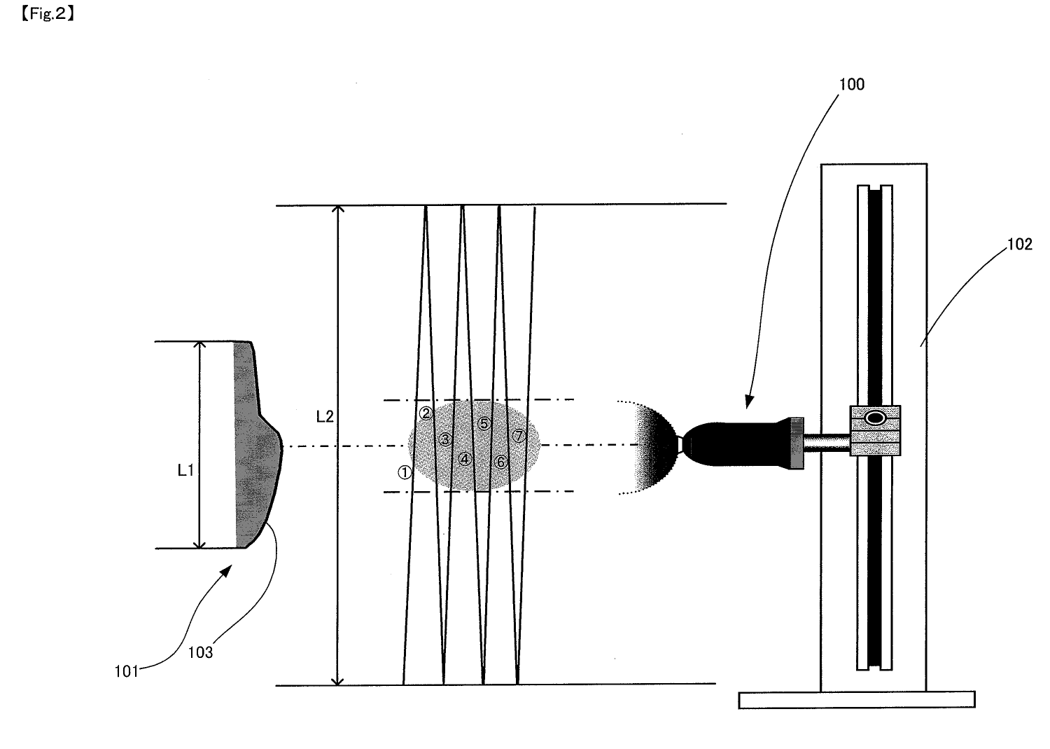

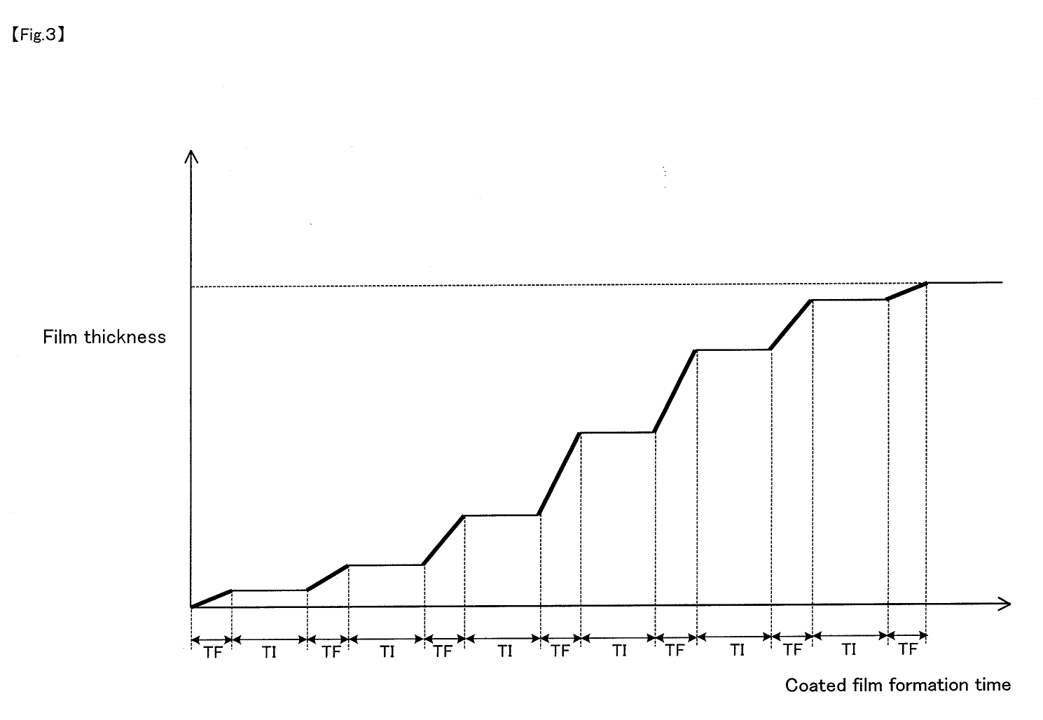

First, a coated film formation profile in an actual coating operation is explained below with reference to FIGS. 2 and 3. FIG. 2 is a an explanatory drawing showing the path of the rotational bell-type atomization coating device 100 over a micro-area portion 103 of a coated object 101 in an actual coating step. FIG. 3 is an explanatory drawing illustrating the relation between the elapse time and the thickness of the coated film in the micro-area portion 103.

In FIG. 2, the rotational bell-type atomization coating device 100 is attached to a vertical reciprocating member 102, and a coating material is sprayed to the object to be coated. In this embodiment, the rotational bell-type atomization coating device 100 passes over the micro-area portion 103 of the coated object 101 seven times, and a spray pattern is coated seven times, forming a coated film.

The floating time (TF) of the atomized particles as the rotational bell-type atomization coating device 100 passes the micro-area portion 103 a single time can be calculated by dividing the passing length of the micro-area portion 103 L1 by reciprocating speed. The rotational bell-type atomization coating device 100 is also reciprocated in those portions other than the micro-area portion 103. The duration of the time in which rotational bell-type atomization coating device 100 passes those portions other than the micro-area portion 103, i.e., the interval TI after the completion of a coating pass in the micro-area portion 103 to the subsequent coating pass, can be calculated by the expression of (TI=(reciprocating width L2−passing distance of the micro-area portion 103 L1)/reciprocating speed). Therefore, a coated film formation profile as shown in FIG. 3 can be obtained when the horizontal axis indicates coated film formation time and the vertical axis indicates coated film thickness. The thickness of the coated film can be measured by such as an electro-magnetic coating thickness meter, laser displacement meter, etc. In FIG. 3, the film thickness is schematically shown by a straight line, but films deposit based on a logistic function in an actual coating operation.

The controller regulates the conveyor 41 so as to produce a coated film formation profile determined by a relation between changes in the coated film formation time and the thickness of the resulting coated film. In other words, the conveyor 41 is controlled depending on the duration of the object 50's passing, number of times the object 50 passes, and the interval TI between the completion of one coating pass and the start of the subsequent coating pass in the spray pattern of the coating material sprayed from the rotational bell-type atomization coating device 30 so that these agree with those of the coated film formation profile in an actual coating operation. Note that the conveyor 41 is controlled so that the atomized particles of coating material do not deposit on the object 50 during the interval TI by having the object 50 stand still in or by moving the object 50 to a region in the coating booth where the atomized particles of coating material do not deposit.

This allows to make the deposition of the atomized particles of the coating material sprayed from the rotational bell-type atomization coating device 30 on the object 50 (film deposition behavior) substantially the same as in an actual coating.

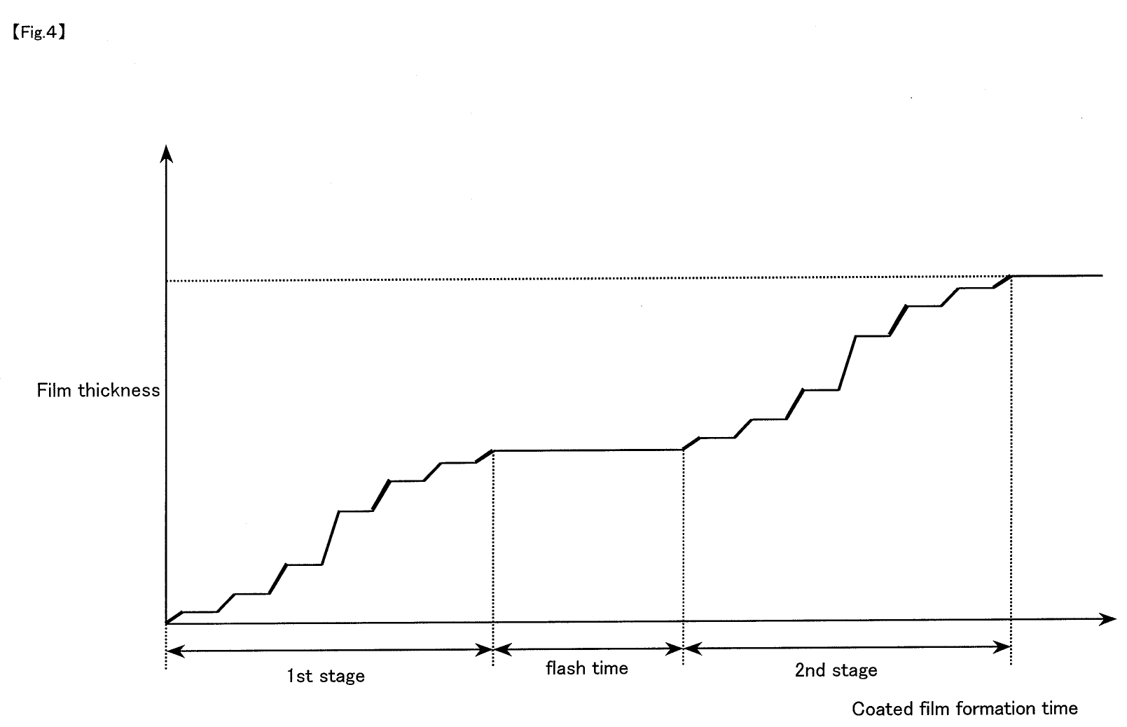

When the actual coating operation is to be conducted by 2-stage coating, i.e., the object is overcoated after previously conducting coating, as shown in the coated film formation profile of FIG. 4, flash time is provided between the completion of coating in the first stage and the start of coating in the second stage wherein no coating is conducted. When coating in the actual coating operation is to be conducted by two times of coating with one flash time, by suitably setting the interval T1 so as to correspond to the timing of the flash time, the deposition (deposition behavior) of atomized particles of the coating material sprayed from rotational bell-type atomization coating device 30 on the object 50 can be made substantially the same as in the actual coating operation.

In multi-stage coating wherein the object is coated with a coating material three or more times, it is possible to make the deposition behavior substantially the same as in the actual coating operation by suitably setting the intervals T1 in such a manner that they correspond to the plurality of times flash time.

As described above, the film forming equipment 1 of the present embodiment can reproduce coating conditions in an actual coating operation by controlling temperature and humidity of the air in a coating booth 22, the particle diameter, concentration, and velocity of atomized particles of a coating material spayed from a rotational bell-type atomization coating device 30, and deposition behavior of the atomized particles deposited on an object 50 so that they are substantially the same as in an actual coating operation. Therefore, a coated film having a finished quality substantially the same as one obtained in an actual coating operation can be formed.

Furthermore, because coated films can be formed uninfluenced by the skills of the operator conducting the coating operation, coated films having uniform finished quality can be effectively formed without quality variations caused by human factors.

The film forming equipment 1 can be miniaturized by using a compact coating material atomizer instead of a coating material atomizer as usually used in an actual coating operation. This reduces the space necessary for installing the film forming equipment 1, and energy consumption for conditioning air. Furthermore, since a coated film can be formed on an object 50 using a small amount of coating material, waste of coating material is significantly reduced.

One embodiment of the present invention is explained above; however, the specific embodiment of the present invention is not limited to the above-described embodiment. For example, the present embodiment has a structure in which an object 50 is transferred by a conveyor 41 in such a manner that the object 50 passes through the spray pattern of the coating material sprayed from the rotational bell-type atomization coating device 30; however, the present embodiment may have the following structure. By being attached to a conveyor 41, the rotational bell-type atomization coating device 30 is moved so as to make the spray pattern pass over the object 50. Such a structure allows to reproduce a coated film formation profile in an actual coating operation even if the object 50 is too big and difficult to be moved by the conveyor 41. This structure likewise makes it possible to form a coated film having substantially the same finished quality as that to be obtained in an actual coating operation.

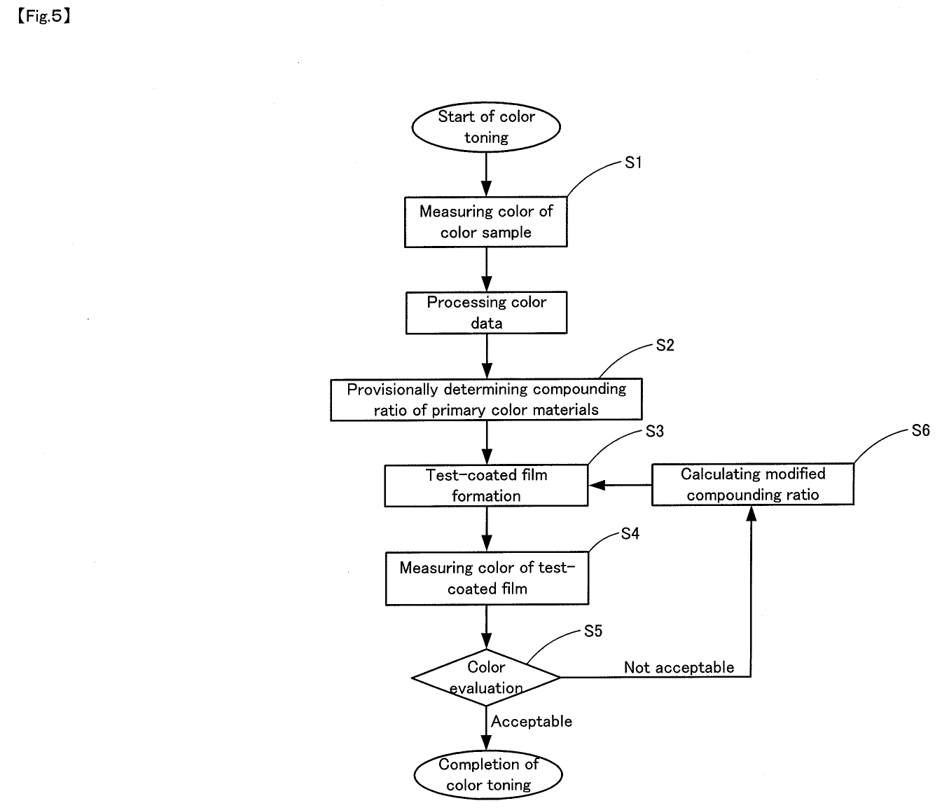

Use of the film forming equipment 1 of the present embodiment enables a desired color-toning coating material to be obtained in an effective manner. A method for preparing a color-toning coating material is explained below with reference to the flow chart of FIG. 5 illustrating a color-toning procedure.

First, color data of a color sample having the same color as that to be obtained are measured (color measurement step S1). A calorimeter that can measure spectral reflectance of the color sample is used for the measurement of color data of the color sample. A multi-angled calorimeter usable for measurement of metallic color coating is particularly preferable. The obtained color sample data are subjected to data processing and sorting.

Second, based on the obtained color data of the color sample, a provisional compounding ratio of coating materials of a plurality of primary colors is determined (provisional compounding ratio determination step S2). It is preferable that the provisional compounding ratio of the coating materials of a plurality of primary colors be determined by using computer color matching (CCM). Computer color matching (CCM) is a technique wherein a compounding ratio of primary color coating materials to achieve a desired color is predictively calculated using a computer. Usually, such calculation is conducted in the following manner: spectral reflectance of the color sample is measured; prospective reflectance of an estimated color having a specific compounding ratio of a plurality of primary color coating materials or other coloring agents is calculated based on the basic data, i.e., spectral reflectance of a coated chip sample coated with a primary color coating material; and by comparing the prospective reflectance with the reflectance of the color sample, a compounding ratio of the primary color coating materials of the estimated color is calculated so that the hue of the estimated color agrees with that of the color sample. In this case, if the reflectance variance between the color sample and the estimated color is greater than a predetermined value, the compounding ratio of the primary color coating materials is altered so that its reflectance falls in a predetermined range, and if it falls within the predetermined range, such compounding ratio is deemed to be the compounding ratio for the primary color coating materials for achieving the desired color.

A color-toning coating material comprising coating materials each having a different primary color according to the provisional compounding ratio obtained in the provisional compounding ratio determination step S2 is sprayed onto a test panel, forming a test coated film (test coated film formation step S3). Formation of a test coated film is conducted by using the film forming equipment 1 of the present embodiment. In other words, the test coated film is formed under substantially the same coating conditions as those in the actual coating operation.

Subsequently, color data of the test coated film formed by using the film forming equipment 1 are measured (test coated film color measurement step S4). Measurement of the color data of the test coated film is conducted in the same manner as the measurement of the color data of color samples. The obtained color data of color samples are subjected to data processing and sorting.

The color data of the color sample are compared with the color data of the test coated film, and the color conformity between the color sample and the test coated film is evaluated based on predetermined evaluation standards (color evaluation step S5). When the color conformity between the color sample and the test coated film meets the evaluation standards, preparation of a color-toning coating material is completed, and the compounding ratio of the coating materials for a plurality of primary colors of the color-toning coating material sprayed in the test coated film formation step S3 is deemed to be the compounding ratio for obtaining the desired color-toning coating material. The thus-obtained color-toning coating material is then output.

In contrast, when the color conformity between the color sample and the test coated film does not meet the evaluation standards, the provisional compounding ratio of primary color coating materials determined in the provisional compounding ratio determination step S2 is altered (compounding ratio modification step S6). In the test coated film formation step S3, a color-toning coating material comprising coating materials of a plurality of primary colors having the modified compounding ratio is sprayed onto a test panel to form another test coated film. The color data of the test coated film formed from a color-toning coating material prepared based on the modified compounding ratio is measured again in the test coated film color measurement step S4, and the color conformity between the color sample and the test coated film after the modification is evaluated in the color evaluation step S5. In this manner, the test coated film formation step S3, test coated film color measurement step S4, and the color evaluation step S5 are repeated until the evaluation standards are met in the color evaluation step S5.

In the compounding ratio modification step S6, based on the variance between the color data of the color sample and that of the test coated film (color difference), a modification value for the provisional compounding ratio of primary color coating material is obtained. Such a modification value can be obtained, for example, by using computer color matching (CCM), and the previously obtained provisional compounding ratio of primary color coating material is modified using the thus-obtained modification value.

Such a method for preparing a color-toning coating material can significantly reduce the number of times color toning conducted in the color-toning operation, and a color-toning coating material having excellent color conformity with the color sample of the desired color can be efficiently obtained. In other words, because the test coated film formed on a test panel in the test coated film formation step S3 is obtained under substantially the same conditions as those in the actual coating operation, it is possible to prevent variation in finished quality of the coated film due to differences in the coating conditions of the color-toning operation in the test coating step and the actual coating operation. This makes it possible to effectively obtain a color-toning coating material having the same color as the color sample. Furthermore, because variance in the color data of the color sample and that of the test coated film is attributable only to differences in the compounding ratio of the primary color coating materials, other factors can be eliminated from the possible causes of this variance. Therefore, it is possible to obtain a color-toning coating material having substantially the same color as the desired color sample in a reliable and efficient manner merely by altering the compounding ratio of the coating materials for a plurality of primary colors.

### EXAMPLES

The present invention is explained in detail with reference to Examples.

An embodiment having a coating booth 22 with a cross-sectional area of about 50 cm×40 cm according to the film forming equipment 1 of FIG. 1 is explained below. Such dimensions scale to about 1/100 those of a standard automatic coating booth (standard booth: about 5 m×4 m) used in a coating step.

In FIG. 1, air having its temperature and humidity conditioned by an air conditioning system 10 (manufactured by Apiste Corporation) is supplied to an air supply chamber 21 in the coating equipment main body 20. The air conditioning system 10 controls the air so as to have a specific temperature and humidity by constantly feedbacking signals from temperature and humidity sensors provided in a supply duct. The air conditioned so as to have a specific temperature and humidity is fed to the coating booth 22 via an air supply filter 24. The air becomes a downflow having an average air velocity of about 0.3 m/sec, and is discharged through an exhauster provided in an exhaust chamber 23 via a dust-collecting filter 25. A conveying jig 42 is disposed at a location about 5 cm above the dust-collecting filter 25.

An aqueous metallic-base coating material (“TB-510”, manufactured by Kansai Paint Co., Ltd.) was diluted so as to have a solids content while coating of 23 wt %. Table 1 shows the coating conditions of each stage in a standard booth when a coated film having a desired thickness (dry thickness) of 13 to 15 μm was formed by two-stage coating (flash time of about 2 minutes) using the above-obtained aqueous metallic-base coating material. Table 1 also shows the conditions for producing the coated film formation profile.

The particle diameter in the spray pattern under the above coating conditions at the coating distance was about 21 to 23 μm, the atomized particle concentration was about 0.25 cm³/cm²·min, and the atomized particle velocity was about 7 to 8 m/sec. Table 2 shows the coating conditions for obtaining a coated film formed under such coating conditions by using the film forming equipment 1 of the present invention. The coating conditions shown in Table 2 correspond to those of each stage in the two-stage coating having a flash time of about 2 minutes, and these conditions can reproduce the conditions for obtaining a coated film formation profile in an actual coating operation.

Coating was conducted on a test panel of 5 cm×5 cm under the coating conditions shown in Table 2 as an example. The amount of coating material sample used for obtaining a coated film having substantially the same quality as that obtained in a standard booth was about 12 cc. The finished quality of the test coated chip (I) coated in the actual coating operation under the conditions shown in Table 1 was compared to that of the test coated chip (II) coated using the equipment of the present invention under the conditions shown in Table 2. The test coated chip (I) had a coated thickness of about 12 to 15 μm, and an IV value of 256 to 260, and the test coated chip (II) had a coated thickness of about 13 to 14 μm, and an IV value of 258 to 259. Therefore, a coated film having substantially the same finished quality as that obtained under the coating conditions of the actual coating operation was reproduced.

Note that the “IV value” is a short for “intensity value” and is a measure of brightness. The IV value is a characteristic value indicating the orientation, metallic feel, etc., of a bright pigment used in a coated film. The greater the IV value, the better is the orientation and brightness of the bright pigment. The IV value can be measured by using, for example, “ALCORP” (an IV value measuring apparatus) manufactured by Kansai Paint Co., Ltd.

TABLE 1

Rotation speed: 30000 rpm
(Bell Diameter: 70 mm φ)
Shaping air flow rate: 600 nl/min
Flow rate of the coating material: 240 cc/min
Gun distance: 20 cm
Applied voltage: −60 kv
Coating space: 5 m × 4 m × 2.5 m
Temperature: 20~30 ± 0.5° C.
Humidity: 40~80 ± 2% RH
Pattern width: 35 cm(350 mm)
Conveyor speed: 3 m/min(5 cm/sec)
Reciprocating speed: 60 m/min(100 cm/sec)
Reciprocating width: 100 cm
<Coated film formation profile>
Deposition time: about 0.35 sec/1 stroke
Interval of coating: about 0.65 sec
Coating times: 6

TABLE 2

Rotation speed: 10000 rpm
(Bell Diameter: 30 mm φ)
Flow rate of the coating material: 20 cc/min
Shaping air flow rate: 200 nl/min
Gun distance: 5 cm
Applied voltage: −15 kv
Coating space: 50 cm × 40 cm × 40 cm
Amount coating supplied: 20 cc or less
Temperature: 20~30 ± 0.5° C.
Humidity: 40~80 ± 2% RH
Pattern width: 10 cm(100 mm)
Transferred speed
in X-axis direction: 285 mm/sec(100 mm/0.35 sec)
Transferred speed
in Y-axis direction: 25 mm/sec(16 mm/0.65 sec)

Another embodiment is explained below. In this example, a coated film having substantially the same finished quality as that obtained in an actual coating operation is formed by using air-atomizing type coating equipment that atomizes a coating material by compressed air instead of the coating material atomizer 30 of the film forming equipment 1. The coating material used was a solvent-based silver metallic coating material (“SF420T” manufactured by Kansai Paint Co., Ltd.). Table 3 shows the coating conditions of each stage in a standard coated film formation process wherein a coated film having a desired thickness (dry thickness) of 13 to 15 μm was formed by two-stage coating (flash time of about 2 minutes) using this coating material. Table 3 also shows the conditions of the coated film formation profile.

The particle diameter in the spray pattern under the above coating conditions at the coating distance was about 20 μm, the atomized particle concentration was about 0.255 cm³/cm²·min, and the atomized particle velocity was about 12 m/sec. Table 4 shows the coating conditions for producing a coated film obtained under these conditions by using a film forming equipment 1 using air-atomizing type coating equipment instead of the coating material atomizer 30. The coating conditions shown in Table 4 correspond to those of each stage in the two-stage coating having a flash time of about 2 minutes, and these conditions makes it possible to reproduce the conditions for the coated film formation profile in an actual coating operation.

A test panel of 7.5 cm×15 cm was coated under the coating conditions shown in Table 4. The finished quality of the test coated chip (III) coated in an actual coating operation under the conditions shown in Table 3 was compared to that of the test coated chip (IV) coated using the equipment of the present invention under the conditions shown in Table 4. Such a comparison was made by using the color difference ( [symbol] E) obtained based on the brightness (L-value) measured using a multi-angled calorimeter (MA68II: manufactured by X-Rite). The results show that none of the color differences measured at five different angles (i.e., 15°, 25°, 45°, 75°, and 110°) were greater than 1.0. It was also confirmed by visual inspection that substantially the same colors were obtained.

TABLE 3

Spray gun: manufactured by BINKS
Atomized pressure: 3.5 kg/cm²
Gun distance: 30 cm
Gun speed: 500 (mm/sec)
Slide stroke: 500 (mm)
Pitch shift speed: 500 (mm/sec)
Transfer pitch: 75 (mm)
Over coating pitch: 0.075 (m)
Transfer efficiency: about 60 (%)
Spray pattern width: 30 (cm)
Atomized particle concentration: 0.255
Average atomized coating particle diameter: about 20 μm
Flow rate of the coating material: 300 (cc/min)
<Coated film formation profile>
Coating interval: 1.15 (sec)
Coating times: 4
Deposition time: 0.6(sec/1 stroke)

TABLE 4

Spray gun: manufactured by ASAHI SUNAC
Atomized pressure: 1 kg/cm²
Gun distance: 15 cm
Transferred speed in X-axis direction: 167 (mm/sec)
Stroke in X-axis direction: 150 (mm)
Transferred speed in Y-axis direction: 100 (mm/sec)
Stroke in Y-axis direction: 25 (mm)
Over coating pitch: 0.025 (m)
Transfer efficiency: about 80 (%)
Spray pattern width: 10 (cm)
Atomized particle concentration: 0.255
Average atomized coating particle diameter: about 20 μm
Flow rate of the coating material: 25 (cc/min)
<Coated film formation profile>
Coating interval: 1.148 (sec)
Coating times: 4
Deposition time: 0.599(sec/1 stroke)

1. A method for forming a coated film,
which aims to reproduce finished qualities of a coated film to be obtained in an actual coating operation by spraying a coating material onto an object to be coated,
the method for forming the coated film comprising:
an air conditioning step of controlling the temperature and humidity in a coating booth in accordance with the spraybooth conditions in the actual coating operation; and
a coating step of forming a coated film on an object to be coated in the coating booth using an atomizer for spraying a coating material;
the coating step comprising:
a coating condition determination step of controlling particle diameter, concentration and velocity of the atomized particles in the spray pattern of coating material sprayed from the coating material atomizer in accordance with those in the actual coating operation; and
a coated film formation step of controlling the relative movement of the coating material atomizer and the object being coated based on a coated film formation profile determined by the relation between changes in the coated film formation time in the actual coating operation and the resulting coated film thickness.

2. The method for forming a coated film according to claim 1, wherein the coated film formation step comprises a step of controlling the relative movement of the coating material atomizer and the object to be coated based on the coating pass velocity, number of coating passes, and length of the interval between the completion of one coating pass and the start of the subsequent coating pass in the spray pattern of the coating material sprayed from the coating material atomizer.

3. The method for forming a coated film according to claim 1, wherein the coating condition determination step comprises a step of selecting a suitable concentration of atomized particles depending on the flow rate of the coating material sprayed from the coating material atomizer relative to the area of the pattern to be formed on the object to be coated by the spray pattern of coating material sprayed from the coating material atomizer.

4. The method for forming a coated film according to claim 1, wherein the coating material atomizer is a rotational bell-type atomization coating device, and the coating condition determination step comprises a step of selecting the particle diameter by suitably controlling the diameter and the rotational rate of the bell and the flow rate of the coating material from the rotational bell-type atomization coating device.

5. The method for forming a coated film according to claim 1, wherein the coating material atomizer is a rotational bell-type atomization coating device, and the coating condition determination step comprises a step of determining the velocity of the atomized particles by suitably selecting the flow rate of shaping air from the rotational bell-type atomization coating device and the coating distance.

6. The method for forming a coated film according to claim 1, wherein the coating material atomizer is a device for atomizing the coating material by using compressed air, and the coating condition determination step comprises a step of selecting the atomized particle diameter by suitably controlling the air flow rate and the flow rate of the coating material.

7. The method for forming a coated film according to claim 1, wherein the coating material atomizer is a device for equipment for atomizing the coating material by using compressed air, and the coating condition determination step comprises a step of selecting the velocity of the atomized particles by suitably controlling the air flow rate and the coating distance.

8. A device for forming a coating film,
which aims to reproduce the finished quality of a coated film to be obtained by spraying a coating material onto an object to be coated in an actual coating operation; the device for forming a coating film comprising:
an air conditioner that can control temperature and humidity in a coating booth;
a coating material sprayer for spraying a coating material onto an object to be coated in the coating booth;
a conveyor for moving the object to be coated and the coating material sprayer in a relative manner in the coating booth; and
a controller for controlling the operation of the air conditioner, the coating material sprayer, and the conveyor;
the controller being able to control the particle diameter, concentration, and velocity of atomized particles sprayed from the coating material sprayer, and control the relative movement of the coating material atomizer and the object to be coated based on a coated film formation profile determined by the relation between changes in the coated film formation time in the actual coating operation and the resulting coated film thickness.

9. The device for forming a coated film according to claim 8, wherein the controller controls the movements of the coating material atomizer and the object to be coated in a relative manner based on the coating pass velocity, number of coating passes, and length of the interval between the completion of one coating pass and the start of the subsequent coating pass in the spray pattern of the coating material sprayed from the coating material atomizer.

10. The device for forming a coated film according to claim 8, wherein the conveyor is a biaxial actuator.

11. A method for preparing a color-toning coating material, which aims to obtain a desired color-toning coating material, comprising:
a color measurement step for measuring color data of a color sample;
a provisional compounding ratio determination step of provisionally determining the compounding ratio of coating materials of a plurality of primary colors according to the color data of the color sample measured in the color measurement step;
a test coated film formation step of preparing a test coated film by spraying onto a test panel a color-toning coating material comprising coating materials of a plurality of primary colors prepared based on the provisional compounding ratio;
a test coated film color measurement step of measuring color data of the test coated film formed in the test coated film formation step;
a color evaluation step of evaluating the color conformity between the color sample and the test coated film by comparing color data of the color sample and those of the test coated film based on predetermined evaluation standards;
the test coated film formation step comprising an air conditioning step of controlling the temperature and humidity in a coating booth in accordance with the actual coating operation; and a coating step of forming a test coated film on the test panel by spraying a color-toning coating material using a coating material atomizer in the coating booth;
the coating step comprising:
a coating condition determination step of controlling particle diameter, concentration and velocity of atomized particles in the spray pattern of coating material sprayed from the coating material atomizer in accordance with those in the actual coating operation; and
a coated film formation step of controlling the movement of the coating material atomizer and the test panel to be coated in a relative manner based on a coated film formation profile determined by the relation between changes in the coated film formation time in the actual coating operation and the resulting coated film thickness.

12. A method for preparing a color-toning coating material according to claim 11, wherein, when it is determined that the color conformity does not meet the evaluation standards in the color evaluation step, the test coated film formation step further comprises a step of forming a subsequent test coated film using a color-toning coating material prepared by modifying the provisional compounding ratio of primary color coating materials.
